(19) United States
(12) Patent Application Publication
(10) Pub. No.: US 2011/0126884 A1
(43) Pub. Date: Jun. 2, 2011

(54) PHOTOVOLTAIC PANEL SUPPORT BASE ROTATING SIMULTANEOUSLY AROUND A HORIZONTAL AND A VERTICAL AXIS

(76) Inventor: Vasileios Dritsas, Nafplio (GR)

(21) Appl. No.: 12/995,747

(22) PCT Filed: Jun. 2, 2009
(86) PCT No.: PCT/GR09/00035

§ 371 Date: Feb. 8, 2011

(30) Foreign Application Priority Data
Jun. 2, 2008 (GR) 20080100372

(51) Int. Cl. H01L 31/052

(52) U.S. Cl. 136/246

(57) ABSTRACT

A Photovoltaic panel support base rotating simultaneously around two axes, i.e. around an horizontal axis (North-South direction) for the continuous correction of the swivel angle (β), and around a vertical axis (East-West direction) for the continuous correction of the hour angle (ω), the solar deviation (δ) and the azimuthal surface (γ). The assembly comprises the tower (1), the base (2) with round profile, used for the anchorage and the seat of the assembly, the first drive mechanism (3) with ball bearings (16) for the rotation of the upper part around a vertical axis, the cantilevers' support assembly (4) of V shape, the rod (5), the second mechanism (7) for the rotation of the photovoltaic panels plane around an horizontal axis, the rotation axis (6) of the photovoltaic panels plane, the beams (8) of changing thin walled profile H and the series of transverse thin walled beams (9) of U profile. The frames of the photovoltaic panels rest on the frame formed by the U-shaped beams. The strong wind which falls at the photovoltaic panel plane is received and transmitted to the inner part of the construction, from one hand by the beams assembly (8) of shape H and from the other by the V-shaped assembly of the cantilevers (4). The strong forces' flow to the increasing profiles of the two assemblies (8) and (4) significantly decreases their strength to the inner part of the construction and as a result the two rotating drive mechanisms (3) and (7) substantially receive minimum dynamic stressing having the form of contact voltages (Hertz) created to their ball bearings (16). The electric motors of the two rotation mechanisms are driven by means of satellite control in order for the combination of β, ω, δ and γ to provide the instantly desired result cos θ=1 or Θ=0, i.e. the incident solar radiation to always be vertical with regard to the panels plane.

### CROSS-REFERENCE TO RELATED APPLICATION

### Statement Regarding Federally Sponsored Research or Development

n/a

### FIELD OF THE INVENTION

The present invention relates to a method and system for a photovoltaic panel support base construction rotating simultaneously around two axes, i.e. around an horizontal axis (North-South direction) for the continuous correction of the swivel angle (β), and around a vertical axis (East-West direction) for the continuous correction of the hour angle (ω), the solar deviation (δ) and the azimuthal surface (γ), providing a photovoltaic panel plane pivoted on two axes with continuous and adjustable drive, in order for the incident solar radiation to be as vertical as possible with regard to the panels surface.

The incidence angle Θ of the solar radiation to a sloping surface is the angle between the incident solar rays and the vertical with regard to the surface. The incidence angle Θ of the solar radiation with regard to a sloping surface is estimated by the equation:

cos Θ=sin δ sin Φ cos β−sin δ cos Φ sin β cos γ+cos δ cos Φ cos β cos ω+cos δ sin Φ sin β cos γ cos ω+cos δ sin β sin γ sin ω.

Where stable (Φ) is the latitude of the installation location and the remaining angles have been defined above and can change during the rotations around the one and the other axis. Therefore, when the combination of the β, ω, δ and γ of the above equation provides a transient instantly desired result cos θ=1 or Θ=0, the incident solar radiation becomes vertical to the panels surface. This can be achieved by the simultaneous and adjustable use of the rotation drive mechanisms to the above mentioned horizontal and vertical axes.

The cost for the photovoltaic panel support bases constitutes a significant part of the total installation cost as the local climatological, weather and environmental conditions of the installation area are taken into consideration during the design stage in order for the best static and dynamic (due to possible strong winds) sufficiency of the construction to be ensured as well as the required resistance to the corrosion (antioxidant protection).

### BACKGROUND OF THE INVENTION

The photovoltaic panel support bases can be divided into two main types: the fixed bases and the movable bases.

The advantage of the fixed support bases is that from one hand no particular maintenance is required, as they do not consist of any moveable parts, and from the other that their design and manufacture cost is significantly lower. Furthermore, no dynamic stressing is created to fixed bases, caused by any moveable parts and movements, but only static stressing due to inertia loading or constant wind fall. The dynamic stressing of fixed bases, due to instant changes of the wind fall, is handled in a milder and symmetric way. The main disadvantage of the fixed support bases is the reduced performance of the photovoltaic panels as only at the solar midday and only at summer there is maximum incident radiation. The fixed support bases are usually situated in such way that the swivel angle (β) is equal to the latitude of the installation area (Φ) in order for the maximum efficiency of the photovoltaic panels to be achieved throughout the year.

The advantage of the movable support bases is the increased efficiency of the photovoltaic panels as the incidence angle of the solar radiation is minimum (zero) due to continuous driving. The main disadvantage of the movable support bases is that there is an increased design and manufacture cost, an additional cost for purchasing ready made parts and products such as motor drive mechanisms, reduction gears, ball or not rotation bearings etc., as well as electrical and electronic equipment for the correct driving, the telecontrol and the remote control of the above drive mechanisms. Furthermore, except for the static stressing due to inertia loading and wind fall, the movable support bases are also under dynamic stressing, due to the movable parts, and the instant changes of the wind forces are handled in a non symmetric way as these bases rotate. Until today the existing movable support bases rotate around a vertical axis (East-West direction) for the continuous correction of the hour angle (ω), the solar deviation (δ) and the azimuthal surface (γ) and around the horizontal axis (North-South direction) for the continuous correction of the swivel angle (β). The North-South direction rotation is usually achieved by the use of drive mechanisms of straight main movement according to which a drive screw brings about the desired torque, for the rotation of the panels plane, by increasing and decreasing its length and by being placed at the end of the support frame of the panels.

The East-West direction rotation is usually achieved by the use of reduction gear mechanisms and in particular of two cooperating gear wheels according to which one electric motor turns the pinion and the said pinion turns the cooperating wheel onto which the support frame of the photovoltaic panels is directly adjusted.

However, in a common assembly of rotation of two axes, as the one described above, the mechanism parts driving the rotation constitute at the same time load carrying members which are under strong dynamic loadings due to random changes of the wind falls, which have an effect to the photovoltaic panel plane, and due to their movement change. In particular, the top or bottom end of the photovoltaic frames is under direct changing wind falls forces which are transmitted by the said end to the screws of straight main movement driving the North-South direction rotation and the said screws transmit them to the cooperating drive gear wheel and finally, to the electric motor causing the movement. In addition, the gear wheel causing the second rotation, i.e. the East-West direction rotation, is under asymmetric dynamic loadings the force of which depends on the instant rotation position of the frame, and the said loadings are transmitted directly to the electric movement motor. Due to all the above there is an uneven and asymmetric stressing of the cooperating gear wheels of movement transmission around the first or the second rotation axis, the changing stressing of the electric motors and the development of vibrations and oscillations at the support frame of the photovoltaic panels.

Another main disadvantage of the known photovoltaic systems is that due to the fact that their movement is achieved by means of drive mechanisms and reduction gear mechanisms, the starting point of the photovoltaic panels is the point of 20° to 30° in relation to the point of 0 degrees, which is considered to be the position point which is vertical with regard to the ground, and as result there exist losses of the produced energy.

### SUMMARY OF THE INVENTION

The present invention advantageously provides a method and system for a photovoltaic panel support base construction rotating around two axes simultaneously, i.e. around an horizontal axis (North-South direction) for the continuous correction of the swivel angle (β) and around a vertical axis (East-West direction) for the continuous correction of the hour angle (ω), the solar deviation (δ) and the azimuthal surface (γ), transmitting, however, the dynamic wind fall loadings to the drive rotation mechanisms through contact voltage (Hertz) created in ball bearings seated at a circular-symmetric assembly around the one and the other rotation axis, capable of evenly receiving the various asymmetries and changes of the dynamic loadings which may be transmitted by the load carrying members of the construction.

Furthermore, a main advantage of the present invention is that a rotation drive mechanism (Slew Drive) is used for the photovoltaic panels movement, by which it is possible for the photovoltaic panels to mechanically achieve a 180° movement and as position point 0 is considered to be the position point which is vertical with regard to the ground. In this way the photovoltaic panels, which are in accordance with the present invention, reach even the 97% of the maximum theoretical yield, as they are in contact with the solar rays for larger period of time.

The present invention refers to a photovoltaic panel support base construction rotating around two axes simultaneously, i.e. around an horizontal axis (North-South direction) for the continuous correction of the swivel angle (β) and around a vertical axis (East-West direction) for the continuous correction of the hour angle (ω), the solar deviation (δ) and the azimuthal surface (γ), transmitting, however, the dynamic wind fall loadings to the drive rotation mechanisms through contact voltage (Hertz) created in ball bearings seated at a circular-symmetric assembly around the one and the other rotation axis, capable of evenly receiving the various asymmetries and changes of the dynamic loadings which may be transmitted by the load carrying members of the construction.

Furthermore, a main advantage of the present invention is that a rotation drive mechanism (Slew Drive) is used for the photovoltaic panels movement, by which it is possible for the photovoltaic panels to mechanically achieve a 180° movement and as position point 0 is considered to be the position point which is vertical with regard to the ground. In this way the photovoltaic panels, which are in accordance with the present invention, reach even the 97% of the maximum theoretical yield, as they are in contact with the solar rays for larger period of time.

### BRIEF DESCRIPTION OF THE DRAWINGS

A more complete understanding of the present invention, and the attendant advantages and features thereof, will be more readily understood by reference to the following detailed description when considered in conjunction with the accompanying drawings wherein:

FIG. 1 shows the present invention which is a photovoltaic panel rotating around two axis simultaneously.

FIG. 2 shows a perspective view and a section view of the rotating drive mechanism.

### DETAILED DESCRIPTION OF THE INVENTION

The technical, constructional and functional characteristics of the invented device, according to the present invention, will be comprehensive to those skilled in the art, with reference to the accompanying drawings of the present specification, which show an indicative industrial preferred embodiment of the present invention.

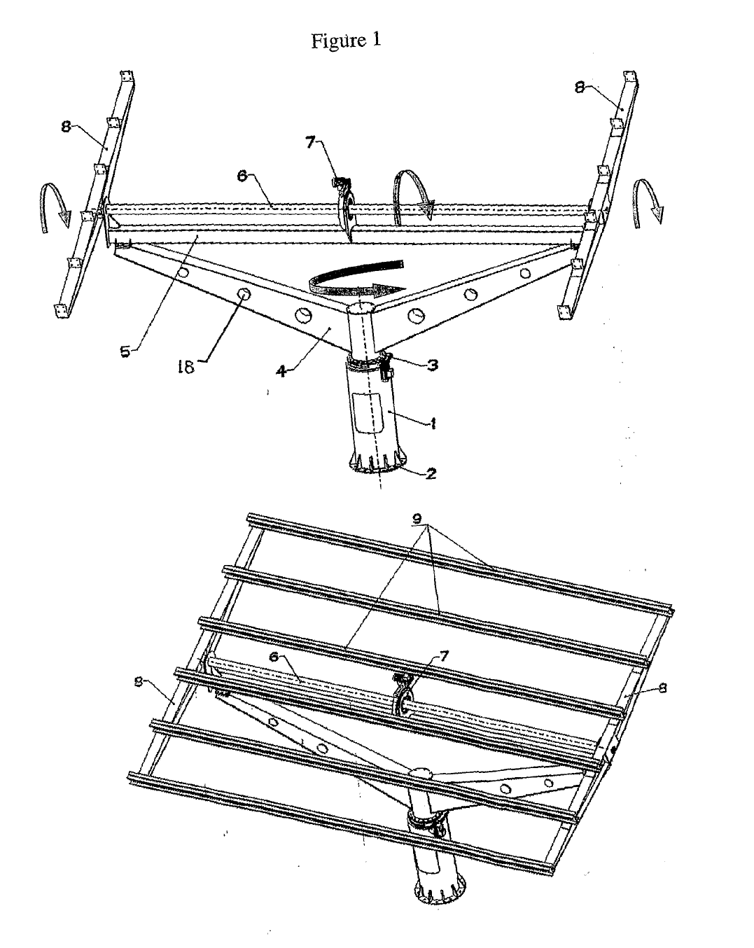

In particular, FIG. 1 shows the present invention which is a photovoltaic panel rotating around two axis simultaneously, i.e. around a horizontal axis (North-South direction) and around a vertical axis (East-West direction).

It constitutes an assembly comprising the following main parts: The tower (1) made of steel pipe with seam and welded steel base of circular profile (2) which is provided with ribs and slots used for the anchorage and the seat of the assembly. The upper part of the tower is assembled by screws, the first drive mechanism (3) with ball bearings (16) for the rotation of the upper part around a vertical axis (East-West direction). A support assembly (4) is fitted to the rotating ring of the mechanism, by means of screws, which is supplied with two steel cantilevers welded in a symmetric way around the vertical rotation, of V shape, on a steel pipe with seam. Each cantilever is made of steel-sheets of appropriate cutting which are welded in such way in order for a changing rectangular profile, which is thin and decreasing from the rotation axis to their ends, to be formed. Each cantilever is provided with three slots (18) of different diameter in order for the air current flow to be allowed. At the top of the V-shaped cantilevers' assembly a steel rod of hollow rectangular thin profile (5) is fitted by means of screws. At the mid part of the said rod (5) a steel semicircular base is welded where the second mechanism is seated and assembled with ball bearings (7) by means of screws, which rotate the photovoltaic panel plane around a horizontal axis i.e. to the North-South direction. At both sides of the hollow rod (5) and at the ends thereof, two steel bearings of semicircular profile are welded which are provided with self lubricated friction rings where the steel hollow rotation axis (6) of the photovoltaic panel plane is seated. At both sides and at the ends of the hollow rotation axis (6) two steel beams (8) of changing thin walled profile H, which is decreasing from the seat hub to the axis and at both sides to the ends, are fitted in a stable and tight way by means of rivets and screws. A series of transverse thin walled beams (9) of U profile, fitted at the end beams by means of screws, bridge the gap between the two beams (8). The frames of the photovoltaic panels rests on the formed frame of the U-shaped beams (9). The driving of the rotating mechanism (3) causes the rotation of the whole upper part (4), (5), (6), (7), (8), (9) around a vertical axis (East-West direction).

Simultaneously and regardless of the previous rotation, the driving of the rotation mechanism (7) causes the rotation around the horizontal axis (North-South direction) of the whole support section of the photovoltaic panel plane (6), (8), (9).

Therefore, the support frame (9) of the photovoltaic panels is simultaneously and independently turned around two axes (vertical and horizontal). Furthermore, the strong wind which falls at the photovoltaic panel plane is received and transmitted to the inner part of the construction from one hand by the beams assembly (8) of changing shape H and from the other by the V-shaped assembly of the cantilevers of changing profile (4). The strong forces' flow to the increasing profiles of the two assemblies (8) and (4) significantly decreases their strength to the inner part of the construction and as a result the two rotating drive mechanisms (3) and (7) substantially receive minimum dynamic stressing. The electric motors of the rotation mechanisms are driven by means of satellite control in order for the combination of β, ω, δ and γ to provide an instantly desired result cos θ=1 or Θ=0, i.e. the incident solar radiation to always be vertical with regard to the panels plane.

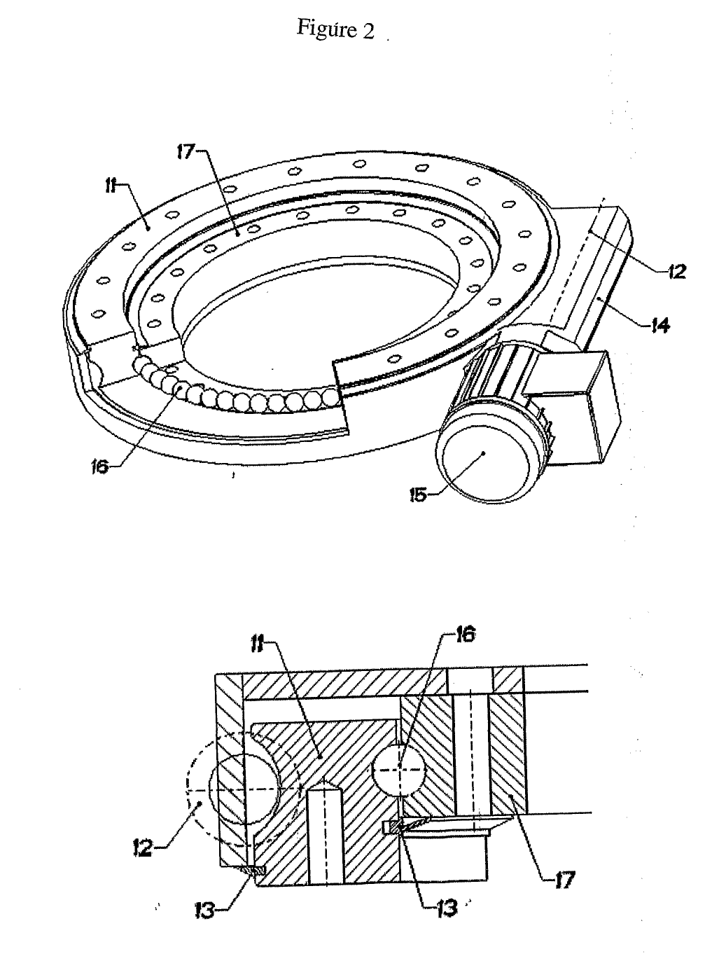

FIG. 2 shows a perspective view and a section view of the rotating drive mechanism (Slew Drive) which constitutes a ready made assembly available in the market and is provided with a drive rotation mechanism the operation of which is based on the known co-operation between the endless gear screw with the gear ring or “crown” as it is known.

The Slew Drive mechanism comprises a particularly resistant rotating gear ring (11), the rotation transmission element which is the endless gear screw (12), the gaskets (13), the bearing where the endless screw is situated (14) and the electric or hydraulic drive (15). The ball bearings (16) transmit the loading between the external rotating ring (11) and the internal stable ring (17). The system's resistance to the loadings handling efficiency is mainly determined by the hardness, the number and the diameter of the ball bearings. Spacers are situated between the ball bearings which rotate with them and minimize the friction and the corruption. A lubricator is fitted at the internal stable ring for lubricating the ball bearings the uniformity of which is achieved by the rotation of the external ring. The distribution and the direction of the contact voltages, created at the ball bearings, vary depending on the external loading. In case only axial stable loading is created, all the ball bearings are charged in a symmetric way with the same contact voltages and have the same direction. In case radial load is created, only a part of the ball bearings handles the high contact voltages. In case an inclined instant voltage is created, a part of the bearings on the one side and a part of the bearings on the opposite side handles the contact voltages. Usually, a combination of axial, radial and inclined instant voltages is formed during the embodiment of the Slew Drive at the rotating support bases of photovoltaic panels, due to the changes in the strength and the direction of the wind fall loadings.

It will be appreciated by persons skilled in the art that the present invention is not limited to what has been particularly shown and described herein above. In addition, unless mention was made above to the contrary, it should be noted that all of the accompanying drawings are not to scale. A variety of modifications and variations are possible in light of the above teachings without departing from the scope and spirit of the invention, which is limited only by the following claims.

What is claimed is:

1. Photovoltaic panel support base rotating simultaneously around a horizontal and a vertical axis for the continuous correction of the swivel angle (β), of the hour angle (ω), the solar deviation (δ) and the azimuthal surface (γ), characterized in that it comprises a tower (1), a base (2) with ribs used for the anchorage and seat of the assembly, the first drive mechanism (3) (Slew Drive) for the rotation of the upper part around a vertical axis, the support assembly (4), the rod (5), the two bearings with self lubricated friction rings and base where the second drive mechanism (7) (Slew Drive) is seated for the rotation of the photovoltaic panels plane around an horizontal axis, the rotation axis (6) of the photovoltaic panels plane, the beams (8) of changing thin walled profile H and a series of transverse thin walled beams (9) of U profile, which form a frame supporting the frames of the photovoltaic panels.

2. Photovoltaic panel support base rotating simultaneously around a horizontal and a vertical axis, according to claim 1, characterized in that the support assembly (4) rotates around a vertical axis, as it rests on the rotating ring (11) of the mechanism (3) and comprises two cantilevers of V shape which are in symmetry with regard to the rotation axis made of steel-sheets of appropriate cutting which are welded in such way in order for a changing rectangular profile which is thin and decreasing from the rotation axis to their ends to be formed and each one is provided with three slots (18) of different diameter in order for the air current flow to be allowed.

3. Photovoltaic panel support base rotating simultaneously around a horizontal and a vertical axis, according to claim 1, characterized in that the support frame (9) of the photovoltaic panels rotates around the horizontal axis as it is situated on the two beams (8) of changing thin walled profile H which is decreasing towards their ends which are fitted in a stable way by means of rivets to the rotation axis (6) which is fitted to the rotating ring of mechanism (7).

4. Photovoltaic panel support base rotating simultaneously around a horizontal and a vertical axis, according to claim 1, characterized in that each rotation mechanism (3) and (7) is located at its rotation axis respectively and it comprises a gear screw or endless gear screw (12), a gear external ring or “crown” (11) on which the part which will rotate rests, ball bearings (16) which transmit the loading between the external rotating ring (11) and the internal stable ring (17), and as a result it is possible for the photovoltaic panels to mechanically achieve a 180° movement towards the East-West direction and as position point 0 is considered to be the position point which is vertical with regard to the ground.
